(19) United States
(12) Patent Application Publication
(10) Pub. No.: US 2026/0372050 A1
(43) Pub. Date: Nov. 19, 2026

(54) METHOD OF MANUFACTURING INTEGRATED CIRCUIT (IC) DEVICE HAVING STAND-ALONE FEED-THROUGH VIA

(71) Applicant: TAIWAN SEMICONDUCTOR MANUFACTURING COMPANY, LTD., Hsinchu (TW)

(72) Inventors: Cheng-Hua LIU, Hsinchu (TW); Kuang-Hung CHANG, Hsinchu (TW); Guan-Ming HUANG, Hsinchu (TW); Hsieh-Ting-Yang CHENG, Hsinchu (TW); Yuan-Te HOU, Hsinchu (TW)

(21) Appl. No.: 19/749,505

(22) Filed: Jul. 21, 2026

Related U.S. Application Data
(62) Division of application No. 18/756,015, filed on Jun. 27, 2024.

(51) Int. Cl. H10W 20/42; H10W 20/00; H10W 20/41; H10W 20/43

(52) U.S. Cl. CPC H10W 20/42; H10W 20/427; H10W 20/43; H10W 20/435; H10W 20/021

(57) ABSTRACT

A method of fabricating a semiconductor device includes: forming a first circuit having a first pin; forming a second circuit having a second pin; forming a first power conductor such that a first side of the first power conductor faces the first functional circuit; forming a second power conductor; forming a signal connection configured to couple a signal between the first pin and the second pin, the forming the signal connection including: forming a first via structure configured to provide the signal to a back of the substrate, including forming a first feed-through via (FTV); forming a second via structure configured to provide the signal to the front of the substrate, including forming a second FTV; forming a first conductive element to connect the first via structure to the first pin; and forming a second conductive element to connect the second via structure to the second pin.

### CROSS-REFERENCE TO RELATED APPLICATIONS

This application is a divisional application of U.S. patent application Ser. No. 18/756,015, filed Jun. 27, 2024, which is incorporated herein by reference in its entirety.

### BACKGROUND

An integrated circuit (“IC”) device or semiconductor device includes one or more devices represented in an IC layout diagram (also referred to as a “layout diagram”). A layout diagram is hierarchical and includes modules which carry out higher-level functions in accordance with the IC design specifications. The modules are often built from a combination of cells, each of which represents one or more semiconductor structures configured to perform a specific function. Cells having pre-designed layout diagrams, sometimes known as standard cells, are stored in standard cell libraries (hereinafter “libraries” or “cell libraries” for simplicity) and accessible by various tools, such as electronic design automation (EDA) tools, to generate, optimize and verify designs for ICs.

Reducing signal delays, e.g., resistance-capacitance (RC) delays, in an integrated circuit (IC) device or semiconductor device is a design consideration. An approach to reducing signal delays involves reducing distances and/or RC characteristics of wiring connections such as routing connections on front- and back-sides of a substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of an IC device, in accordance with some embodiments.

FIGS. 2A-2B are layout diagrams of an IC device, in accordance with some embodiments, and FIG. 2C is a schematic cross-sectional view of a device corresponding to FIGS. 2A-B.

FIG. 2D is a plan view of an example embodiment of an FTV cell, and FIG. 2E is a schematic cross-sectional view corresponding to FIG. 2D.

FIG. 3 is a flowchart of a method of designing an IC device, in accordance with some embodiments.

FIG. 4 is a schematic diagram of routing using a stand-alone feed-through via, in accordance with some embodiments.

FIG. 5 is a schematic diagram of routing using an embedded feed-through via, in accordance with some embodiments.

FIG. 6 is a schematic diagram of routing using a combination of an embedded FTV and a stand-alone FTV, in accordance with some embodiments.

FIG. 7 is a schematic diagram of routing, in accordance with some embodiments.

FIGS. 8A, 8B, and 8C are layout diagrams of IC devices, in accordance with some embodiments.

FIGS. 9A and 9B are schematic diagrams of RC calculations for a sign-off methodology for a stand-alone FTV cell design, according to some embodiments.

FIG. 10 is a flowchart of a method of generating a layout and using the layout to manufacture an IC device, in accordance with some embodiments.

FIG. 11 is a flowchart of a method of generating a layout, in accordance with some embodiments.

FIG. 12 is a flowchart of a method of fabricating one or more components of an IC device, in accordance with some embodiments.

FIG. 13 is a block diagram of an electronic design automation (EDA) system 1300 in accordance with some embodiments.

FIG. 14 is a block diagram of an integrated circuit (IC) manufacturing system, and an IC manufacturing flow associated therewith, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Source/drain(s) may refer to a source or a drain, individually or collectively dependent upon the context.

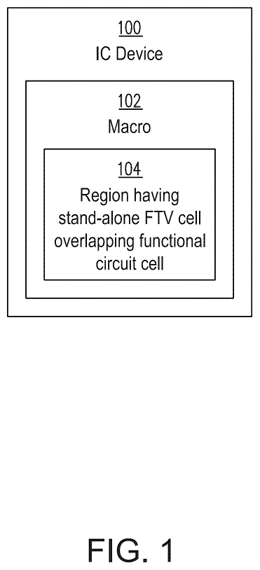

FIG. 1 is a block diagram of an IC device 100 including a feed-through via, in accordance with some embodiments.

A feed-through via (FTV) is a component that extends through a substrate and electrically connects a feature in a layer on a front side of the substrate and a layer on a back side of the substrate, the back side of the substrate being opposite to the front side where active regions are formed.

In FIG. 1, the IC device 100 includes a macro 102. In some embodiments, the macro 102 includes one or more of a memory, a power grid, a cell or cells, an inverter, a latch, a buffer, and/or any other type of circuit arrangement that may be represented digitally in a cell library. In some embodiments, the macro 102 is understood in the context of an analogy to the architectural hierarchy of modular programming, in which subroutines/procedures are called by a main program (or by other subroutines) to carry out a given computational function. In this context, the IC device 100 uses the macro 102 to perform one or more given functions. Accordingly, in this context and in terms of architectural hierarchy, the IC device 100 is analogous to the main program and the macro 102 is analogous to subroutines/procedures. In some embodiments, the macro 102 is a soft macro. In some embodiments, the macro 102 is a hard macro. In some embodiments, the macro 102 is a soft macro which is described digitally in register-transfer level (RTL) code. In some embodiments, synthesis, placement, and routing have yet to have been performed on the macro 102 such that the soft macro can be synthesized, placed, and routed for a variety of process nodes. In some embodiments, the macro 102 is a hard macro which is described digitally in a binary file format (e.g., Graphic Database System II (GDSII) stream format), where the binary file format represents planar geometric shapes, text labels, other information, and the like of one or more layouts of the macro 102 in hierarchical form. In some embodiments, synthesis, placement, and routing have been performed on the macro 102 such that the hard macro is specific to a particular process node.

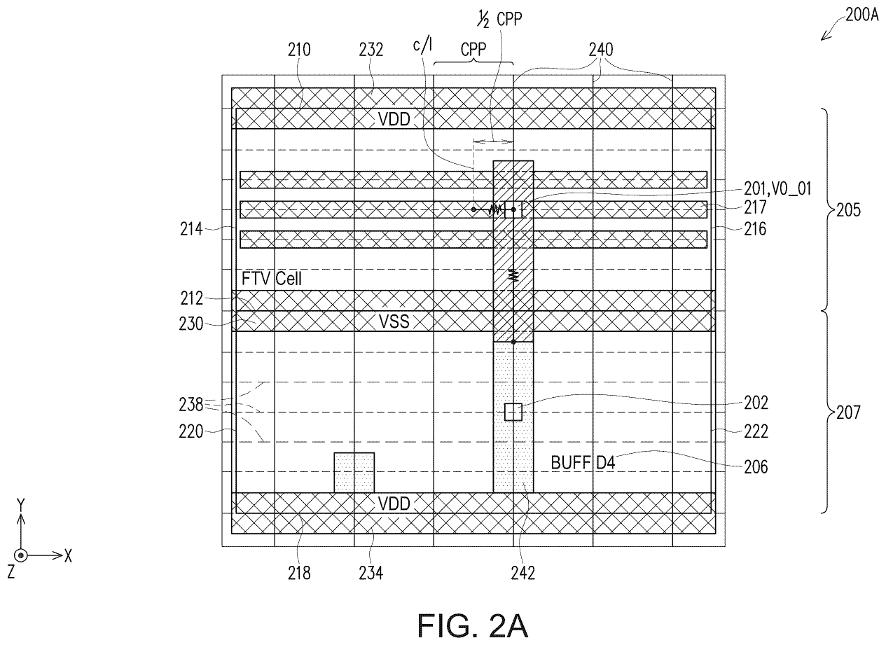

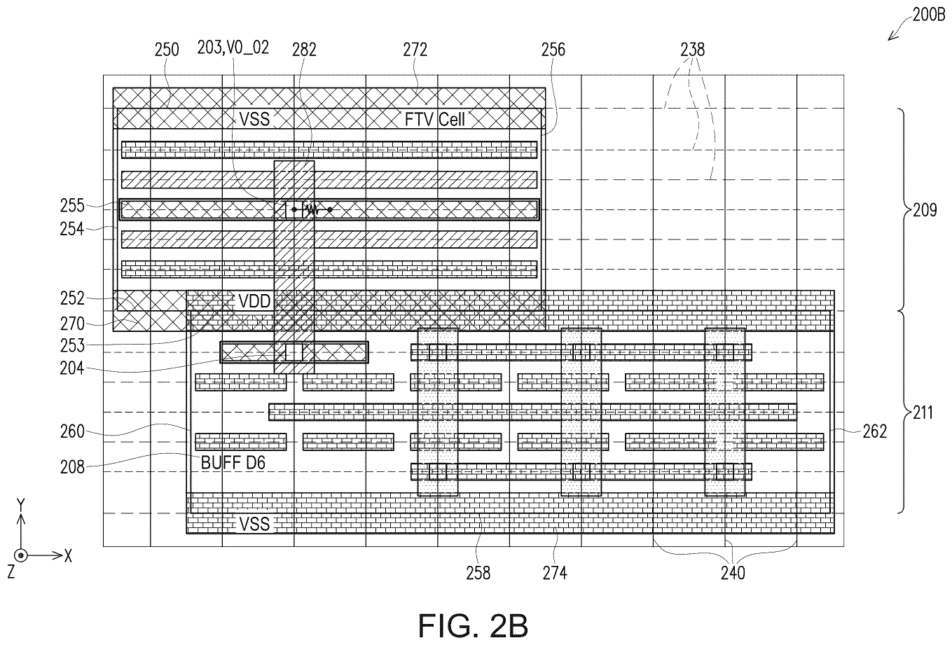

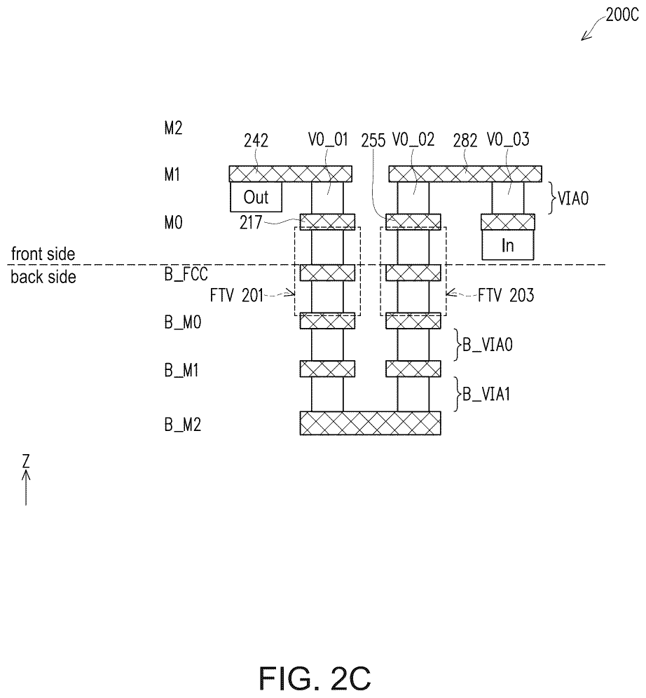

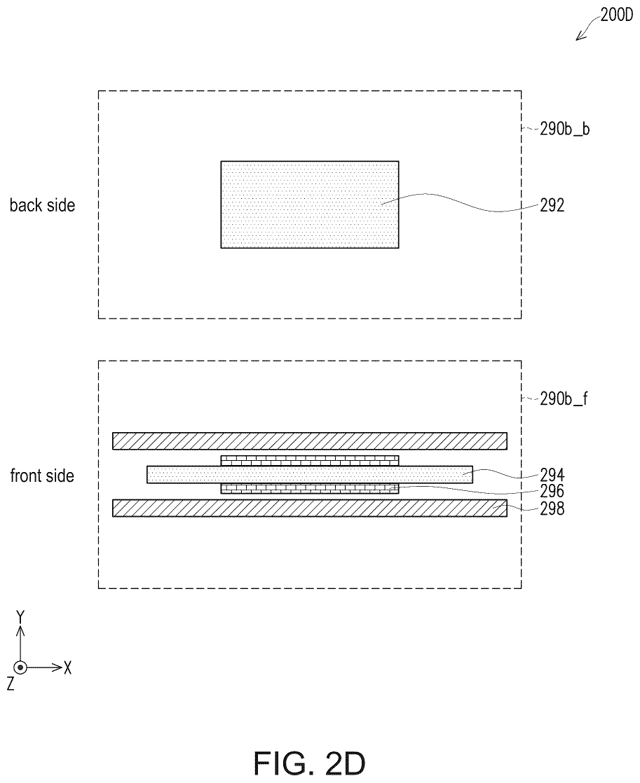

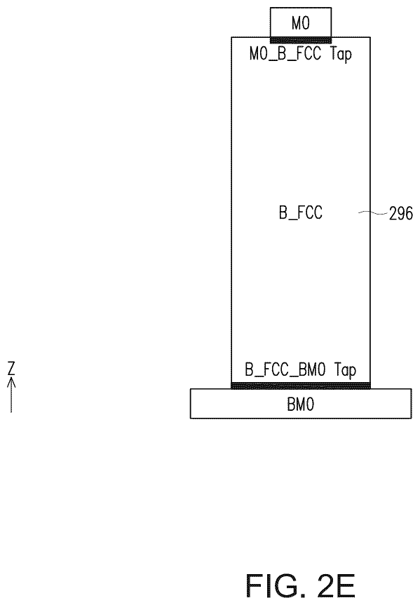

In FIG. 1, the macro 102 includes a region 104 that includes a stand-alone FTV cell overlapping a functional circuit cell, where overlapping refers to having row-direction (X-axis direction in, e.g., FIG. 2A) cell boundaries that are in common for at least a portion of a width of the cells. The stand-alone FTV cell corresponds to a stand-alone FTV in the IC device. The functional circuit cell corresponds to a functional circuit in the IC device. The functional circuit includes at least one active device such as a transistor or the like. In some embodiments, the functional circuit includes logic. In some embodiments, the functional circuit is or includes a buffer, inverter, or the like. In some embodiments, the stand-alone FTV cell is a separate cell in the library. In some embodiments, the stand-alone FTV cell does not include an active device such as a transistor or the like. In some embodiments, the stand-alone FTV cell does not include a functional circuit element such as a buffer, inverter, or the like. In some embodiments, the stand-alone FTV cell does not include logic.

In some embodiments, the region 104 corresponds to a substrate having circuitry formed thereon, in a front-end-of-line (FEOL) fabrication. In the region 104, above and/or below the substrate, various metal layers are stacked over and/or under insulating layers in a back end of line (BEOL) fabrication. The BEOL provides a power network and/or routing for circuitry of the IC device 100, including the macro 102 and the region 104.

In some embodiments, the functional circuit includes one or more active devices, passive devices, logic circuits, or the like. Examples of active devices or active elements include, but are not limited to, transistors, diodes, or the like. Examples of passive elements include, but are not limited to, capacitors, inductors, fuses, resistors, or the like. Examples of logic circuits include circuits that perform AND, OR, NAND, NOR, XOR, INV, AND-OR-Invert (AOI), OR-AND-Invert (OAI), or the like. Other functional circuits include a multiplexer (MUX), flip-flop, buffer (BUFF), latch, delay, clock, memory, or the like. Example memory cells include a static random access memory (SRAM), a dynamic RAM (DRAM), a resistive RAM, a magnetoresistive RAM (MRAM), a read only memory (ROM), or the like.

In some embodiments, an IC device includes one or more feed-through vias (FTVs) that form a signal or power connection between a feature in an M0 layer on a front side of the substrate and a feature in a B_M0 layer on a back side of the substrate. In some embodiments, an IC device includes one or more feed-through vias (FTVs) that connect a signal or power between a feature in a layer other than an M0 layer on a front side of the substrate and a feature in the B_M0 layer or a layer other than a B_M0 layer on a back side of the substrate.

In some embodiments, a FTV is formed by a vertical stack (where vertical refers to a direction perpendicular to a major surface of the substrate) of one or more vias that penetrate the substrate. In some embodiments, the FTV includes a vertical stack of a first via formed from a front side of the substrate and a second via formed from a back side of the substrate, the second via being vertically aligned with and in contact with the first via. Details regarding an approach for forming an FTV are found, e.g., in U.S. Pre-Grant Publication No. 2024/0063093, published Feb. 22, 2024, the entirety of which is hereby incorporated by reference.

In some embodiments, the M0 layer is a metal-0 layer that is a front-side bottommost metal layer (i.e., a first metal layer over the substrate) of an interconnect structure on the front side of the substrate.

On the front side of the substrate, under the M0 layer, an active layer (e.g., a semiconductor layer, an EPI layer, or the like) is formed to provide active regions of transistors or the like. In some embodiments, the active layer is an oxide-defined (OD) layer.

On the front side of the substrate, also under the M0 layer, a metal-to-oxide diffusion (MD) contact layer is formed to connect source/drain (S/D) regions of transistors with other circuit elements or layers. In some embodiments, the MD layer includes features that directly contact the S/D regions of the transistors to couple electrical signals (e.g., voltage or current) to the sources and drains of transistors. In the M0 layer, metal features may extend in a first or X-axis direction (see, e.g., FIG. 2A) that crosses, e.g., is substantially orthogonal to, a second or Y-axis extending direction of gate features (poly features) or MD features in the MD layer.

On the front side of the substrate, also under the M0 layer, another contact layer, a via-on-diffusion (VD) contact layer, is formed to electrically couple features in the MD layer with features in the M0 layer.

On the front side of the substrate, also under the M0 layer, a gate layer or poly layer is formed to provide gates of transistors. In some embodiments, the poly layer includes features that directly overlie the active regions, and which receive electrical signals (gate signals). In some embodiments the gate features and the MD features are formed side-by-side on the active regions. In the poly layer, gate features may extend in a direction that crosses, e.g., is substantially orthogonal to, an extending direction of metal features in the M0 layer.

On the front side of the substrate, also under the M0 layer, another contact layer, a via-on-gate (VG) contact layer, is formed to electrically couple features in the gate layer with features in the M0 layer. In some embodiments, the VG features are interspersed with the VD features at a same level over the substrate.

On the front side of the substrate, over the M0 layer, a via-0 (VIA0) layer is formed to electrically couple features in the M0 layer with features in an M1 layer. In some embodiments, additional metal and via layers are formed on the front side of the substrate, e.g., V1, M2, V2, M3, and the like.

In some embodiments, the B_M0 layer is a backside metal-0 layer that is a back-side bottommost metal layer (i.e., a first metal layer under the substrate) of an interconnect structure on the back side of the substrate.

On the back side of the substrate, over the B_M0 layer, a back-side via-0 (B_VIA0) layer is formed to electrically couple features in the B_M0 layer with features in a B_M1 layer. In some embodiments, additional metal and via layers are formed on the back side of the substrate, e.g., B_VIA1, B_M2, B_VIA2, B_M3, and the like.

FIGS. 2A and 2B are layout diagrams of an IC device, in accordance with some embodiments. FIG. 2C is a schematic cross-section of a device corresponding to FIGS. 2A-B.

In FIG. 2A, a layout 200A includes an FTV 201 that overlaps or is aligned with (along the second or Y-axis direction) a driver pin 202 of a first functional circuit 206, which is a first buffer in some embodiments. In the layout 200A, the FTV 201 and the driver pin 202 are aligned along a second track 240. In FIG. 2B, a layout 200B includes an FTV 203 that overlaps or is aligned with (along the second or Y-axis direction) a sink pin 204 of a second functional circuit 208, which is a second buffer in some embodiments. In the layout 200B, the FTV 203 and the sink pin 204 are aligned along a second track 240. The buffers are each functional circuits, i.e., the buffers have one or more transistors. The layouts 200A, 200B represent regions of an IC device that corresponds to the region 104 of FIG. 1.

In FIG. 2A, a stand-alone FTV cell 205 overlaps a functional circuit cell 207, where the overlap refers to having row-direction (X-axis direction) cell boundaries that are in common for at least a portion of a width of the cells 205, 207 (see common boundary 212 in FIG. 2A). An overall layout of the IC device extends in a first direction (X axis) and a second direction (Y axis) beyond what is shown in FIG. 2A.

In FIG. 2A, the stand-alone FTV cell 205 and the functional circuit cell 207 are in adjacent rows, i.e., the cells 205, 207 are one directly on top of the other in the second direction (Y axis). In an embodiment, the functional circuit cell 207 is in a first row and the stand-alone FTV cell 205 is in a second row that is adjacent to and above the first row. In another embodiment, the functional circuit cell 207 is in a first row and the stand-alone FTV cell 205 is in a second row that is adjacent to and below the first row.

The stand-alone FTV cell 205 has boundaries 210, 212, 214, and 216, with boundaries 210 and 212 extending parallel to the first direction (X axis) and boundaries 214 and 216 extending parallel to the second direction (Y axis). The functional circuit cell 207 has boundaries 212, 218, 220, and 222, with boundary 212 being common with the stand-alone FTV cell 205, boundary 218 extending parallel to the first direction (X axis), and boundaries 220 and 222 extending parallel to the second direction (Y axis).

FIG. 2A shows the stand-alone FTV cell 205 and the functional circuit cell 207 having lateral boundaries that are aligned along the Y-axis direction, i.e., boundary 214 is aligned with boundary 220 along the Y-axis direction, and boundary 216 is aligned with boundary 222 along the Y-axis direction. In other embodiments, the stand-alone FTV cell 205 and the functional circuit cell 207 have different dimensions in the first direction (X-axis) and/or are offset in the first direction (X axis) such that one or both lateral boundaries are not aligned.

In some embodiments, as in FIG. 2A, conductive elements in an M0 layer extend parallel to a first direction (parallel to the X axis) and are arranged in the cells 205, 207 with reference to first tracks 238 (X-axis tracks or horizontal tracks) in the layout 200A. In some embodiments, the first tracks 238 are spaced in the layout 200A (and thus in the cells 205, 207) at a regular pitch along the vertical direction (Y axis).

In FIG. 2A, the common boundary 212 of the row-adjacent cells 205, 207 corresponds to a power or ground element such as a first PG rail 230. In some embodiments, as in FIG. 2A, the boundary 212 is aligned with a middle of a width of the power or ground element, the width being determined in the second direction (i.e., parallel to the Y axis). The boundary 210 of the stand-alone FTV cell 205 corresponds to a second PG rail 232 and the boundary 218 of the functional circuit cell 207 corresponds to a third PG rail 234. In some embodiments, the PG rails are used to provide power or ground to transistors, circuits, or the like formed in cells of the layout 200A. In some embodiments, the PG rails extend beyond the width of one cell, e.g., for an entire length of a row having several or many cells. In some embodiments, the PG rails are formed in the M0 layer. FIG. 2A shows the first PG rail 230 as supplying VSS and the second and third PG rails 232, 234 supplying VDD, but VSS and VDD are reversed in other embodiments and/or other voltages are supplied to the first through third PG rails 230~234. In some embodiments, the lateral boundaries 214, 216, 220, 222 of the cells 205, 207 are defined by one or more CPODE patterns.

In some embodiments, as in FIG. 2A, conductive elements in an M1 layer extend parallel to a second direction (parallel to the Y axis) and are arranged in the cells 205, 207 with reference to second tracks 240 (Y-axis tracks) in the layout 200A. In some embodiments, the second tracks 240 are spaced in the layout 200A (and thus in the cells 205, 207) at a regular pitch along the horizontal direction (X axis). In some embodiments, the second tracks 240 are spaced at a contact poly pitch (CPP) along the X axis. In some embodiments, the CPP is a minimum distance between gate patterns corresponding to gate electrodes in a semiconductor device produced by a process technology node associated with the layout 200A. In some embodiments, the CPP corresponds to a center-to-center distance, along the X axis, of two immediately adjacent gate regions (two gate regions are considered immediately adjacent where there are no other gate regions therebetween). In some embodiments, the CPP is a fundamental unit of measure that has a specific value or range of values for the corresponding semiconductor process technology node. The sizes and/or placement of many other structures in a layout diagram and/or IC device, e.g., conductive lines, can be normalized relative to the CPP.

FIG. 2A shows the driver pin 202 (an output pin) of the functional circuit cell 207 being connected to a conductive element 242 in the M1 layer to a via in the VIA0 layer in the stand-alone FTV cell 205, to a conductive element 217 in the M0 layer in the stand-alone FTV cell 205, and then to the FTV 201. In FIG. 2A, the conductive element 242 vertically overlaps the FTV 201, i.e., overlaps along the Z-axis such that an imaginary line extending parallel to the Z-axis intersects the FTV 201 and the conductive element 242. In FIG. 2A, the conductive element 242 and the FTV 201 have a common Y-axis centerline. In some embodiments, the FTV in the stand-alone FTV cell 205 is located within 1 CPP of the conductive element 242 in the M1 layer and is electrically connected to the conductive element 242. In some embodiments, the FTV in the stand-alone FTV cell 205 is located about ½ CPP or less from a centerline c/l of the stand-alone FTV cell 205. In some embodiments, the FTV in the stand-alone FTV cell 205 is located about ½ CPP or less from the centerline c/l of the stand-alone FTV cell 205. By locating the FTV proximate to the centerline c/l of the stand-alone FTV cell 205, an RC calculation result can be reduced for a situation in which RC calculations are based on a distance from a cell centerline.

The arrangement of the stand-alone FTV cell 205 in the layout 200A of FIG. 2A results in reduced front-side routing due to the ability to avoid M2-layer routing relative to a layout in which the functional circuit cell includes an embedded FTV, due to the stand-alone FTV cell 205 being arranged to overlap (i.e., share a common row-direction boundary) the functional circuit cell 207 rather than using an embedded FTV in a left-hand or right-hand portion of a functional circuit cell. The reduced front-side routing using M1 instead of M2 can result in a reduction of front-side routing resistance of about 50% relative to an embedded-FTV cell that employs a connection structure in which connections are, in sequence, an output pin (M1), VIA1, M2, VIA1, VIA0, and FTV (M0).

In FIG. 2B, a stand-alone FTV cell 209 and a functional circuit cell 211 are row-adjacent, i.e., the cells 209, 211 are one directly on top of the other in the second direction (Y axis). The stand-alone FTV cell 209 has boundaries 250, 252, 254, and 256, with boundaries 250 and 252 extending parallel to the first direction (X axis) and boundaries 254 and 256 extending parallel to the second direction (Y axis). The functional circuit cell 211 has boundaries 253, 258, 260, and 262, with boundary 253 being aligned with the boundary 252 of the stand-alone FTV cell 209, boundary 258 extending parallel to the first direction (X axis), and boundaries 260 and 262 extending parallel to the second direction (Y axis).

FIG. 2B shows the stand-alone FTV cell 209 and the functional circuit cell 211 having offset lateral boundaries, i.e., boundary 254 is offset in the X-axis direction from boundary 260, and boundary 256 is offset in the X-axis direction from boundary 262. In other embodiments, the stand-alone FTV cell 205 and the functional circuit cell 207 have same dimensions in the first direction (X-axis) and/or are aligned in the first direction (X axis) such that one or both lateral boundaries are aligned in the X-axis direction.

In FIG. 2B, conductive elements in the M0 layer extend parallel to the first direction (parallel to the X axis) and are arranged in the cells 209, 211 with reference to the first tracks 238 (X-axis tracks or horizontal tracks) in the layout 200A.

In FIG. 2B, the boundaries 252, 253 of the row-adjacent cells 209, 211 correspond to a power or ground element such as a fourth PG rail 270. In some embodiments, as in FIG. 2B, the boundaries 252, 253 are aligned with a middle of a width of the power or ground element, the width being determined in the second dimension (i.e., parallel to the Y axis). The boundary 250 of the stand-alone FTV cell 209 corresponds to a fifth PG rail 272 and the boundary 258 of the functional circuit cell 207 corresponds to a sixth PG rail 274. In some embodiments, the PG rails are used to provide power or ground to transistors, circuits, or the like formed in cells of the layout 200B. In some embodiments, the PG rails extend beyond the width of one cell, e.g., for an entire length of a row having several or many cells. In some embodiments, the PG rails are formed in the M0 layer. FIG. 2B shows the fourth PG rail 270 as supplying VDD and the fifth and sixth PG rails 272, 274 supplying VSS, but VDD and VSS are reversed in other embodiments and/or other voltages are supplied to the fourth through sixth PG rails 270~274. In some embodiments, the lateral boundaries 254, 256, 260, 262 of the cells 209, 211 are defined by one or more CPODE patterns.

In FIG. 2B, conductive elements in the M1 layer extend parallel to the second direction (parallel to the Y axis) and are arranged in the cells 209, 211 with reference to the second tracks 240 (Y-axis tracks) in the layout 200B.

FIG. 2B shows routing from a conductive element 255 in the M0 layer of the stand-alone FTV cell 209 through a via in the VIA0 layer, a conductive element 282 in the M1 layer, and a via in the VIA0 layer, to the sink pin 204, which is an input pin of the functional circuit cell 211 in the M0 layer.

The arrangement of the stand-alone FTV cell 209 in the layout 200B of FIG. 2B results in reduced front-side routing due to a shorter conductive element in the M0 layer in the stand-alone FTV cell 209 relative to a layout in which the functional circuit cell includes an embedded FTV, due to the stand-alone FTV cell 209 being arranged to overlap with (i.e., share a common X-axis direction boundary with) the functional circuit cell 211 rather than using an embedded FTV in a left-hand or right-hand portion of a functional circuit cell. The reduced front-side routing can result in a reduction of front-side routing resistance of about 60% relative to an embedded-FTV cell that employs a connection structure in which connections are, in sequence, an FTV (M0), VIA0, M1, VIA0, M0, and input pin (M0).

FIG. 2C is a schematic cross-sectional view of a device 200C corresponding to FIGS. 2A-B.

In FIG. 2C, a first via structure includes the FTV 201 and a first via V0_01 in the via-0 layer (VIA0), and a second via structure includes the FTV 203 and a second via V0_02 in the via-0 layer (VIA0). In FIG. 2C, the first and second via structures also include vias in back-side via layers B_VIA0 and B_VIA1 and conductors in back-side metalization layers B_M0 and B_M1. A connection between the first and second via structures is made in a back-side metalization layer B_M2. In other embodiments, depending on routing resources on the back side of the substrate, one or more of the back-side vias and/or back-side conductors are omitted from the via structures, and the connection in B_M2 between the first and second via structures is made in a different back-side metalization layer, e.g., B_M1 or B_M0.

FIG. 2C shows the reduced front-side routing of FIG. 2A using M1 instead of M2 (i.e., output pin (or driver pin) (M1) to M1 to VIA0 to FTV (M0)), which uses M1 instead of M2. FIG. 2C also shows the reduced front-side routing of FIG. 2B (i.e., FTV (M0) to VIA0 to M1 to VIA0 (by via V0_03) to input pin (or sink pin) (M0)). In FIG. 2C, a B_FCC layer corresponds to a simplified layer for an EDA tool to model FTV-related layers during a design process and is used, e.g., for an RC extraction engine and router to identify via stacking during backside routing in the EDA tool, so that the RC engine and router can handle this cell as a via for a one-net structure.

As described above in connection with FIGS. 2A-C, a semiconductor device according to an embodiment includes the first functional circuit 206, e.g., a buffer, in the functional circuit cell 207. The first functional circuit 206 has includes the driver pin 202. The first PG rail 230 extends in the first direction (parallel to the X axis) in the M0 layer (a first layer of metalization) on a front of the semiconductor substrate. The third PG rail 234 extends in the first direction in the M0 layer. The third PG rail 234 is spaced apart from the first PG rail 230 in the second direction (parallel to the Y axis). The first functional circuit 206 is between the third PG rail 234 and a first side (lower side in FIG. 2A) of the first PG rail 230. The second functional circuit 208, e.g., a buffer, is in functional circuit cell 211 and includes the sink pin 204. A signal connection, which includes back-side wiring, couples a signal from the driver pin 202 to the sink pin 204. The signal connection includes the conductive element 242 extending in the second direction (Y-axis) in the M1 layer (a second layer of metalization). The conductive element 242 is connected to the driver pin 202 and crosses from the first side (lower side in FIG. 2A) of the first PG rail 230 to a second side (upper side in FIG. 2A) of the first PG rail 230. The signal connection also includes a first via structure on the second side (upper side in FIG. 2A) of the first PG rail 230, configured to provide the signal from the conductive element 242 to a back of the semiconductor substrate. The first via structure includes the FTV 201 on the second side (upper side in FIG. 2A) of the first PG rail 230. The signal connection also includes a second via structure configured to provide the signal to the front of the semiconductor substrate. The second via structure includes the FTV 203. The signal connection also includes the conductive element 282 extending in the second direction (Y-axis) in the M1 layer. The conductive element 282 is connected to the second via structure and the sink pin 204.

FIG. 2D is a plan view of an example embodiment of an FTV cell 200D with two pins, FTV_F 294 in layer M0 (front side) and FTV_B 292 in layer B_M0 (back side). FIG. 2E is a schematic cross-sectional view corresponding to FIG. 2D.

In FIGS. 2D-E, an RC model uses a simplified model for a signal FTV connection between M0 and B_M0. In the example shown in FIGS. 2D-E, B_FCC combines a middle layer including MD, VD, and FTV-related process layers.

Referring to FIG. 2D, the FTV cell 200D has a place-and-route boundary 290b_b for the back side and a place-and-route boundary 290b_f for the front side. The pin FTV_B 292 in back side metal layer B_M0 is located within the back side place-and-route boundary 290b_b. The pin FTV_F 294 in front side metal layer M0 is located within the front side place-and-route boundary 290b_f. Layer B_FCC 296 overlaps the pin FTV-F 294 along at least one of the X-axis and Y-axis directions. The pin FTV_F 294 and the layer B_FCC 296 are located between M0 layer obstructions 298, relative to the Y-axis direction. FIG. 2E shows the layer B_FCC 296 in cross-section, representing a middle layer, between metal layers M0 and B_M0.

An example of a macro corresponding to FIGS. 2D-E includes the following:

```
MACRO FTV_CELL
  PIN FTV_B
    DIRECTION INOUT ;
    USE SIGNAL ;
    PORT
    LAYER BFCC_B_M0_TAP ;
    RECT ...;
    LAYER B_M0 ;
    RECT ...;
    END
  END FTV_B
  PIN FTV_F
    DIRECTION INOUT ;
    USE SIGNAL ;
    PORT
    LAYER B_FCC ;
    RECT ...;
    LAYER M0 ;
    RECT ...;
    LAYER M0_BFCC_TAP ;
    RECT ...;
  END
END FTV_CELL
```

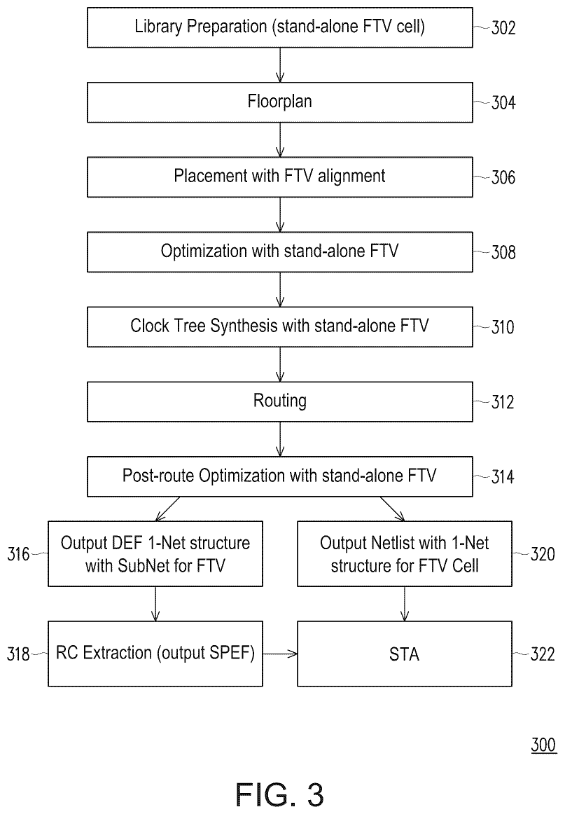

FIG. 3 is a flowchart of a method 300 of designing an IC device, in accordance with some embodiments. In some embodiments, the method 300 of FIG. 3 is included in a method of manufacturing an IC device.

In the method 300, an operation 302 of preparing a library includes preparing a library of standard cells that includes at least one standard cell that is a stand-alone FTV cell, e.g., the stand-alone FTV cell 205 of FIG. 2A. In some embodiments, the library includes standard cells that correspond to functional circuits such as the functional circuit cell 207 of FIG. 2A. In some embodiments, one or more standard cells correspond to functional circuits with embedded FTVs, such that the library contains stand-alone FTV cells and embedded FTV cells.

An operation 304 includes establishing a floorplan of the IC device, such as setting cell sizes, arranging, and allocating space for functional blocks (logic, memory, I/O, power, or the like). In some embodiments, operation 302 includes setting a location of the macro 102 of FIG. 1 on a die.

In operation 306, various circuit elements are placed. Operation 306 includes defining at least one region having a stand-alone FTV cell overlapping a functional circuit cell (see region 104 of FIG. 1).

Following operation 306, an operation 308 of circuit optimization, an operation 310 of clock tree synthesis (CTS), an operation 312 of signal routing (which includes back-side routing), and an operation 314 of post-routing optimization are performed.

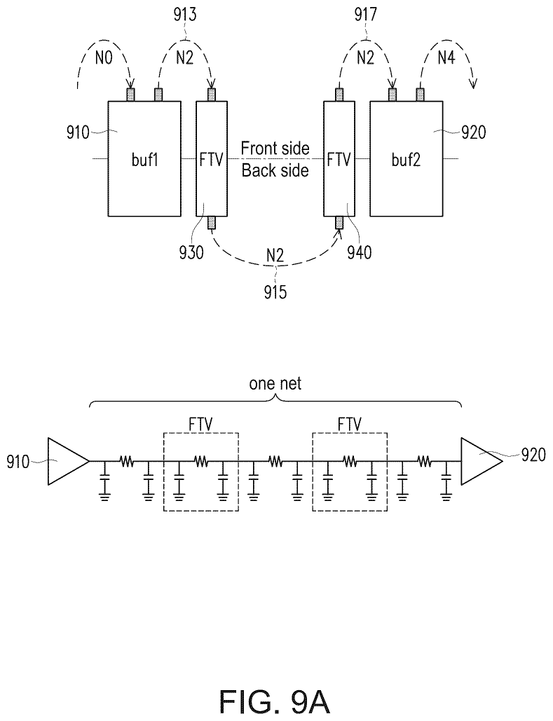

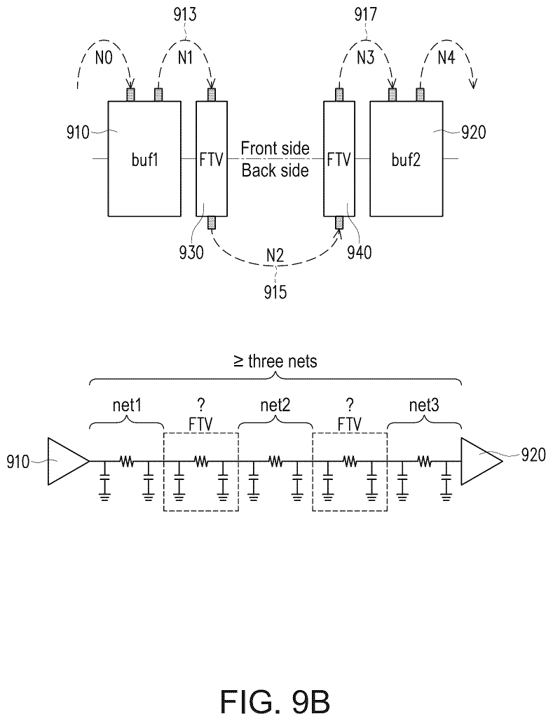

Following operation 314, an operation 316 is performed for generating a Design Exchange Format (DEF) file representing a physical layout of the IC device. Data structures other than a DEF file are used in other embodiments. Operation 316 includes outputting a one-net structure with subnets for the FTVs. In some embodiments, the one-net structure represents a circuit structure that connects two functional circuits and includes at least one FTV and both front-side and back-side routing (an example of the one-net structure is described below in connection with FIG. 9A). As discussed below, in some embodiments the FTV cells are considered in the same manner as a via, i.e., not as a device. In other embodiments, the FTV cells are treated as a device.

A result of operation 316 is used in operation 318 to extract R-C(resistance-capacitance) characteristics of the IC device. Operation 316 includes generating a Standard Parasitic Exchange Format (SPEF) file in some embodiments.

Also following operation 314, an operation 320 is performed for generating a netlist that includes one-net structures for the stand-alone FTV cells.

Finally, in operation 322, a statistical timing analysis (STA) is performed to evaluate timing, e.g., timing-critical routing (including timing-critical back-side routing) or the like, of the IC design. Depending on the outcome of operation 322, one or more of the preceding operations of the method 300 may be repeated.

The above description of the method 300 is based on each of operations 302~322 being performed. However, in some embodiments, one or more of operations 302~322 are omitted, performed in a different order, and/or repeated.

The method 300 employs a standard cell library using a stand-alone FTV cell. As described in detail below, the standard cell library using a stand-alone FTV cell allows for cell placement to be optimized for a layout by using a single cell for the stand-alone FTV, and reduce the size and complexity of the standard cell library. This enables faster layout generation and reduces consumption of system resources such as memory, communications bandwidth, processor cycles, and the like, when designing the IC device. Also, as described above, the method 300 also enables a reduction in front-side routing resistance relative to an IC device that employs only embedded-FTV functional circuit cells. Thus, both the IC design process and the resulting IC device are improved.

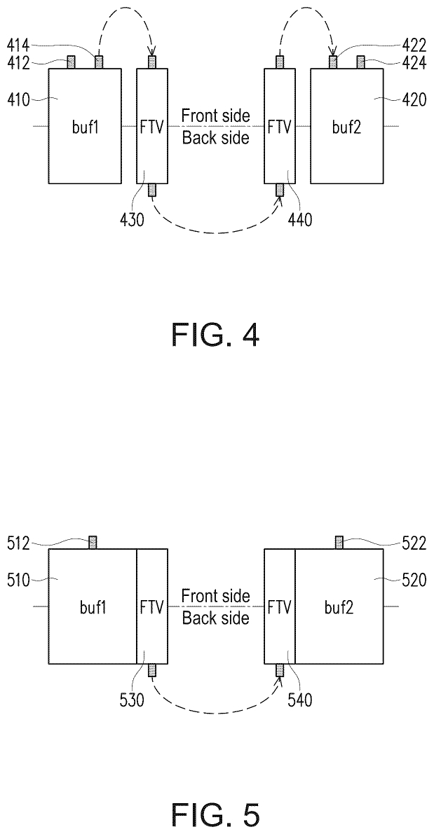

FIG. 4 is a schematic diagram of routing using a stand-alone FTV, in accordance with some embodiments. FIG. 5 is a schematic diagram of routing using an embedded FTV, in accordance with some embodiments.

In some embodiments, an IC device includes functional circuits that are electrically connected by front-side and back-side routing connected by FTVs, at least some of which are implemented using stand-alone FTV cells. FIG. 4 is an example of connecting front-side and back-side routing using stand-alone FTV cells. An IC device in accordance with some embodiments is laid out using stand-alone FTV cells as in FIG. 4, and may further include routing based on the use of embedded FTV cells as in FIG. 5.

In FIG. 4, a first two-pin device 410 is a buffer in some embodiments. A second two-pin device 420 is also a buffer in some embodiments. It will be understood that the first device 410 and the second device 420 can be the same or different, can have the same or different numbers of pins, and can be functional circuits other than buffers.

In FIG. 4 the first device 410 includes a first pin 412 and a second pin 414, and the second device 420 includes a third pin 422 and a fourth pin 424. For clarity of illustration, connections are not shown to the first pin 412 or the fourth pin 424 although such connections are present. The first to fourth pins 412, 414, 422, 424 are on the front side of the substrate. Connections between the second pin 414 and the third pin 422 include back-side routing using a first stand-alone FTV 430, which routes a signal from the second pin 414 on the front side of the substrate to the back side of the substrate, and a second stand-alone FTV 440, which routes the signal from the back side of the substrate to the third pin 422 on the front side of the substrate. The layout of the first device 410, the second device 420, the first FTV 430, and the second FTV 440 is made using stand-alone FTV cells for the first FTV 430 and the second FTV 440.

In FIG. 5, a first device 510 is a buffer in some embodiments. A second device 520 is also a buffer in some embodiments. It will be understood that the first device 510 and the second device 520 can be the same or different, can have the same or different numbers of pins, and can be functional circuits other than buffers.

The first device 510 includes a first pin 512, and the second device 520 includes a second pin 522. The first and second pins 512, 522 are on the front side of the substrate. Connections between the first pin 512 and the second pin 522 include back-side routing using a first embedded FTV 530 (which is embedded with the first device 510) and a second embedded FTV 540 (which is embedded with the second device 520). The layout of the first device 510 and the second device 520 is made using embedded FTV cells, in which the cells for the functional circuits (i.e., the buffers) include the corresponding FTVs 430, 440.

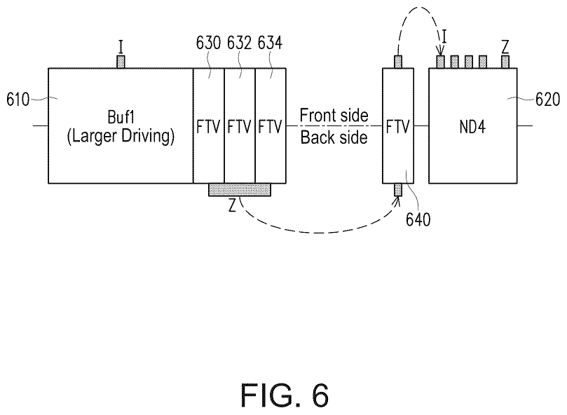

Although FIG. 5 appears to be schematically less complex than FIG. 4, in practice the embedded FTV cells of FIG. 5 exhibit routing RC costs relative to the stand-alone FTV cells of FIG. 4 due to additional front-side routing. That is, as discussed above in connection with FIG. 2A, the layout of the stand-alone FTV cells for the first and second FTVs 430, 440 in FIG. 4 results in reduced front-side routing relative to a layout in which the functional circuit cell includes an embedded FTV, as in FIG. 5. Additionally, as discussed in detail below, implementing a device using embedded FTV cells as in FIG. 5 involves a trade-off between area penalties (due to large cell areas for embedded FTV cells) and library complexity (due to the large number of area-optimized standard cells for embedded FTV cells, if area penalties are to be avoided). However, despite the embedded FTV cells imposing some limitations, it may be desirable in some instances to use the embedded FTV cells in combination with the stand-alone FTV cells in an IC device. This will now be described in connection with FIG. 6.

FIG. 6 is a schematic diagram of routing using a combination of an embedded FTV and a stand-alone FTV, in accordance with some embodiments.

In FIG. 6, a first device 610 is a large driving buffer in some embodiments. A second device 620 is generally indicated as a sink that receives a signal from the first device 610. The first device 610 is implemented using an embedded FTV cell and the routing to the second device 620 is implemented using a stand-alone FTV cell. More particularly, the first device 610 is shown as including embedded FTVs 630, 632, and 634 (the number of embedded FTVs can be less than three or greater than three), and the routing to the second device 620 is shown as using a stand-alone FTV 640. The mixed-cell implementation of FIG. 6 allows for flexibility and ease of routing, e.g., wider and less complex routing for higher current circuit paths, while maintaining at least some of the advantages, e.g., reduced front-side routing, afforded by a layout that uses stand-alone FTV cells.

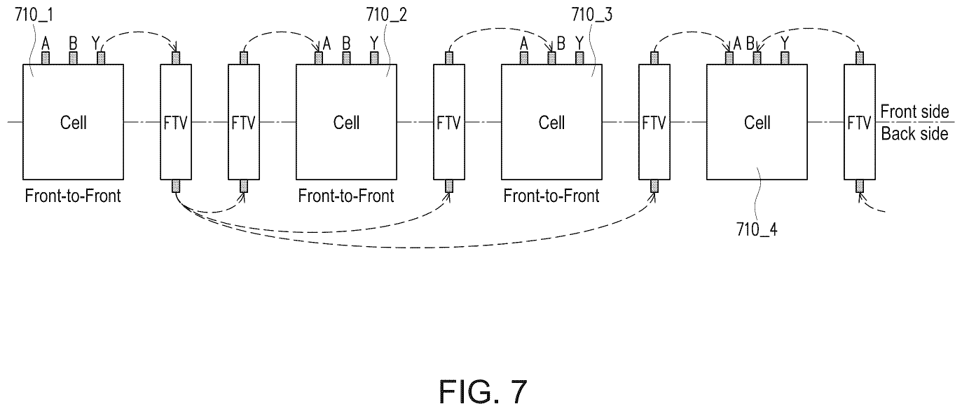

FIG. 7 is a schematic diagram of routing, in accordance with some embodiments.

In FIG. 7, stand-alone FTV cells are used to implement front-side and back-side routing for a first series of three-pin cells.

In FIG. 7, a first functional circuit cell 710_1 is connected to a second functional circuit cell 7102, a third functional circuit cell 710_3, and fourth functional circuit cell 710_4 using routing that includes stand-alone FTV cells. The first through fourth functional circuit cells 701_1-710_4 are the same.

A standard cell library according to some embodiments is simplified using the stand-alone FTV cells as compared to a standard cell library that uses standard cells that have embedded FTVs. In FIG. 7, all of the first through fourth functional circuit cells 710_1-710_4 can be the same, e.g., with all pins on the front side. In a library of embedded FTV cells, to provide area savings for a layout, the standard cells with an embedded FTV and multiple input pins should be included in the library in all combinations of front-side input pins and back-side input pins.

In further detail, FIG. 7 uses one functional circuit cell having front-side pins only, in combination with one stand-alone FTV cell, whereas embedded FTV cells have various combinations to connect front-to-back, back-to-back, and back-to-front, which results in a more complex library. For example, for an embedded FTV cell having 2 input pins and 1 output pin (3 pins in total), 2³⁼⁸ cells should be included in the library for the 3-input-pin cell. Moreover, a cell library becomes rapidly more complex when including embedded FTV cells with more pins and, at the same time, providing standard cells for all combinations of front-side input pins and back-side input pins. For example, each embedded FTV 4-pin cell should be provided as 2⁴⁼¹⁶ cells, each embedded FTV 5-pin cell should be provided as 25=32 cells, each embedded FTV 6-pin cell should be provided as 2⁶=64 cells, and so on, such that, for each embedded-FTV 10-pin cell, 2¹⁰=1024 cells should be provided in the cell library.

A standard cell library using a stand-alone FTV cell according to some embodiments allows for a layout to be optimized using a single functional circuit cell and a single cell for the stand-alone FTV, thereby reducing the size and complexity of the standard cell library. This enables faster layout generation and reduces consumption of system resources such as memory, communications bandwidth, processor cycles, and the like. According to some embodiments, an IC design using stand-alone FTV cells allows front-side-pins-only cells (i.e., cells having only front-side pins) to be routed using back-side routing layers with a relatively simple cell library, i.e., without the larger and more complex library that would be used when routing of back-side pins of multiple-input-pin cells.

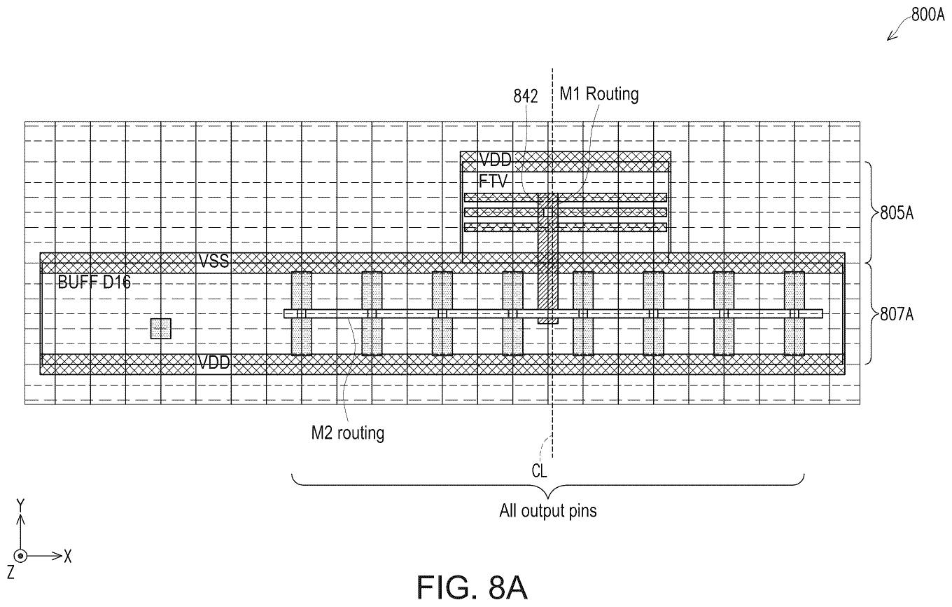

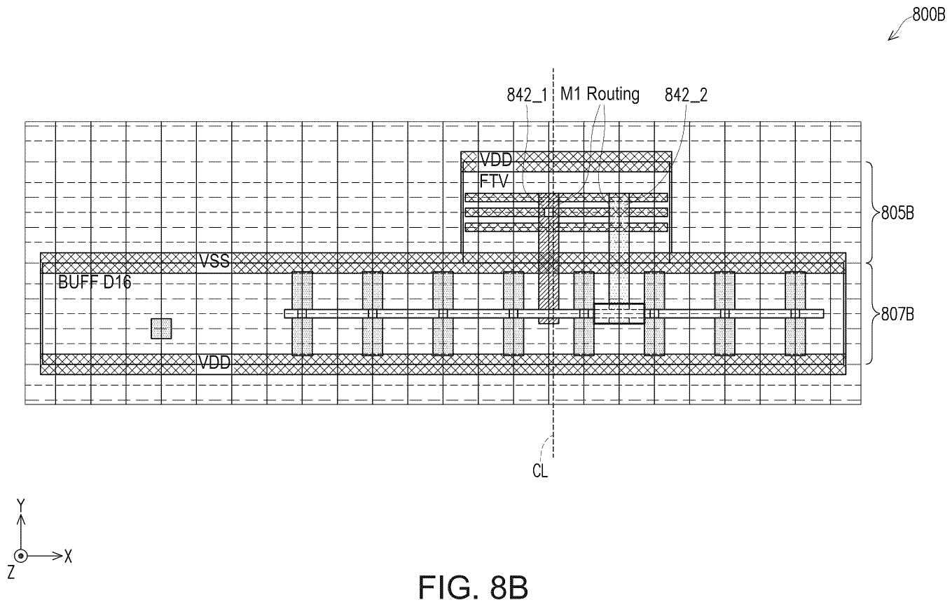

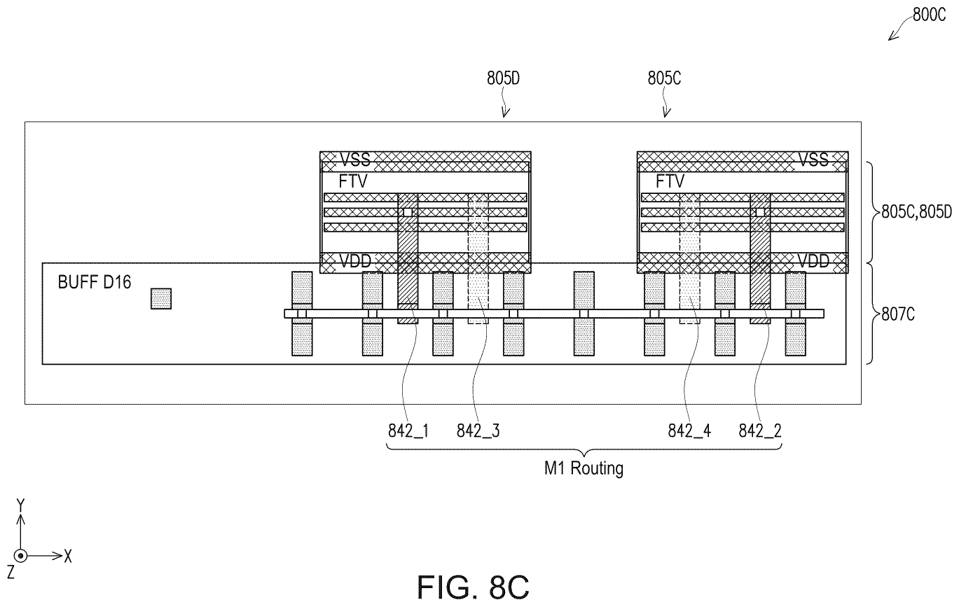

FIGS. 8A, 8B, and 8C are layout diagrams of IC devices, in accordance with some embodiments.

The embodiments of FIGS. 8A-8C use various placement and routing of stand-alone FTV cells connected to a functional circuit cell.

Referring to FIG. 8A, a layout 800A includes a stand-alone FTV cell 805A connected to a functional circuit cell 807A. The functional circuit cell 807A is a large driving cell (a multiple-output-pin buffer) in some embodiments. A larger driving cell is used in some embodiments to drive a correspondingly wider net.

The layout 800A includes a single M1 routing connection between the stand-alone FTV cell 805A and the functional circuit cell 807A. In some embodiments, the use of routing in M1 rather than M0 allows for a lower-resistance connection because routing can be made wider in M1 than in M0. In the layout 800A, a conductive element 842 in the M1 layer extends parallel to the Y axis between the stand-alone FTV cell 805A and the functional circuit cell 807A. The conductive element 842 is substantially centered along a centerline CL of the output pins of the functional circuit cell 807A relative to the X axis.

Referring to FIG. 8B, a layout 800B includes a stand-alone FTV cell 805B connected to a functional circuit cell 807B. The functional circuit cell 807B is a large driving cell in some embodiments. The layout 800B includes multiple M1 routing connections to reduce resistance. In the layout 800B, first and second conductive elements 8421, 842_2 in the M1 layer extend parallel to the Y axis between the stand-alone FTV cell 805B and the functional circuit cell 807B.

Referring to FIG. 8C, a layout 800C includes a first stand-alone FTV cell 805C and a second stand-alone FTV cell 805D, each connected to a functional circuit cell 807C. The functional circuit cell 807C is a large driving cell in some embodiments. Using multiple stand-alone FTV cells can further reduce front-side routing resistance for back-side routing nets. The layout 800C includes a single M1 routing connection (conductive elements 842_1, 842_2 illustrated with solid lines) or multiple M1 routing connections (conductive elements 842_1, 842_2 illustrated with solid lines and conductive elements 8423, 842_4 illustrated with dashed lines) to the stand-alone FTV cells 805C, 805D, in various embodiments.

FIGS. 9A and 9B are schematic diagrams of net structures for a sign-off methodology for a stand-alone FTV cell design, according to some embodiments.

In FIG. 9A, a sign-off methodology treats an FTV net in a netlist as a one-net structure (denoted as net N2). This approach enables the use of traditional sign-off operations (e.g., Automatic Place-and-Route (APR) flow, statistical timing analysis (STA), RC verification calculations to calculate the resistance and capacitance of routed interconnects, and/or formal verification).

Using the one net-based sign-off methodology of FIG. 9A allows the FTV RC components to be considered as part of wiring RC, thus simplifying RC calculations. This approach avoids changes in delay and STA calculations. However, APR flow becomes more involved due to the database structure being modified to split a net into front-side and back-side parts for physical implementation.

In FIG. 9A, a first buffer 910 and a second buffer 920 are connected using a first stand-alone FTV 930, which routes a signal from the front side of a substrate to the back side of the substrate, and a second stand-alone FTV 940, which routes the signal from the back side of the substrate to the front side of the substrate. The first FTV 930 and the second FTV 940 are made using stand-alone FTV cells according to some embodiments. Routing on the front side of the substrate includes front side routing elements (e.g., conductive elements in a wiring layer, or the like) including a first front-side routing element 913 and a second front-side routing element 917. Routing on the back side of the substrate includes a back-side routing element 915. The first and second front-side routing elements 913, 917, the back-side routing element 915, and the first and second FTVs 930,940 are collectively considered to be one net, denoted as a first net N2. This is schematically shown in FIG. 9A as a series of RC components combined as one net between the first buffer 910 and the second buffer 920.

In FIG. 9B, a sign-off methodology treats the FTV net as a net structure of at least three nets (the first and second front-side routing elements 913, 917 and the back-side routing element 915; N1~N3). This approach can use a database structure that is less complex than the approach in FIG. 9A because separate nets are used for front-side and back-side parts, but can result in RC and/or STA calculation complexities in the case that RC components of the FTVs 930, 940 are not included, are unknown, or are not known with sufficient accuracy, because the STA timing path is broken by the FTV cells. Thus, the sign-off methodology of FIG. 9B should model characteristics such as FTV cell timing and crosstalk to provide a more accurate STA. Also, data structures such as an SDF (Standard Delay Format) file or a SPEF (Standard Parasitic Exchange Format) file should be updated to assess the FTV cell RC contributions, and corresponding enhancements should be made to delay and STA calculations.

Referring again to FIG. 9A, a layout versus schematic (LVS) verification according to an embodiment is implemented to treat the FTVs as vias, rather than as a distinct device. In one example, the one-net structure of FIG. 9A is omitted from a Verilog or Simulation Program with Integrated Circuit Emphasis (SPICE) netlist:

| | | |
|---|---|---|
| BUFF | buf1(.Z(N2), | .I(N0)); |
| BUFF | buf2(.Z(N4), | .I(N2)); |

In the above example, buf1 is the first buffer 910 and buf2 is the second buffer 920. NO represents an input to the first buffer 910, N2 represents a net connecting the first buffer 910 to the second buffer 920 and including the FTVs 930, 940, and N4 represents an output of the second buffer 920. In some embodiments, the above example is used in a place and route (PNR) operation for a digital circuit.

In another example, the one-net structure of FIG. 9A treats the FTVs as devices that are included in a Verilog or SPICE netlist:

| | | |
|---|---|---|
| BUFF | buf1(.I(N0), | .Z(N2)); |
| FTV | ftv1(.I(N2), | .Z(N2)); |
| FTV | ftv2(.I(N2), | .Z(N2)); |
| BUFF | buf2(.I(N2), | .Z(N4)); |

In the above example, buf1 is the first buffer 910, ftv1 is the first FTV 930, ftv2 is the second FTV 940, and buf2 is the second buffer 920. NO represents an input to the first buffer 910, N2 represents routing from the first buffer 910 to the second buffer 920 (including the first and second FTVs 930, 940 and front- and back-side routing thereto), and N4 represents an output of the second buffer 920. In some embodiments, the above device-based example is used to evaluate an analog circuit.

Referring again to FIG. 9B, the LVS verification is not implemented to treat the FTVs as vias, in contrast to FIG. 9A. Rather, the LVS verification describes the FTV connections using the three-net, device-based approach in a Verilog or SPICE netlist:

| | | |
|---|---|---|
| BUFF | buf1(.I(N0), | .Z(N1)); |
| FTV | ftv1(.I(N1), | .Z(N2)); |
| FTV | ftv2(.I(N2), | .Z(N3)); |
| BUFF | buf2(.I(N3), | .Z(N4)); |

In the above example, buf1 is the first buffer 910, ftv1 is the first FTV 930, ftv2 is the second FTV 940, and buf2 is the second buffer 920. NO represents an input to the first buffer 910, N1 represents front-side routing from the first buffer 910 to the first FTV 930, N2 represents back-side routing from the first FTV 930 to the second FTV 940, N3 represents front-side routing from the second FTV 940 to the second buffer 920, and N4 represents an output of the second buffer 920. In some embodiments, the above device-based example is used to evaluate an analog circuit.

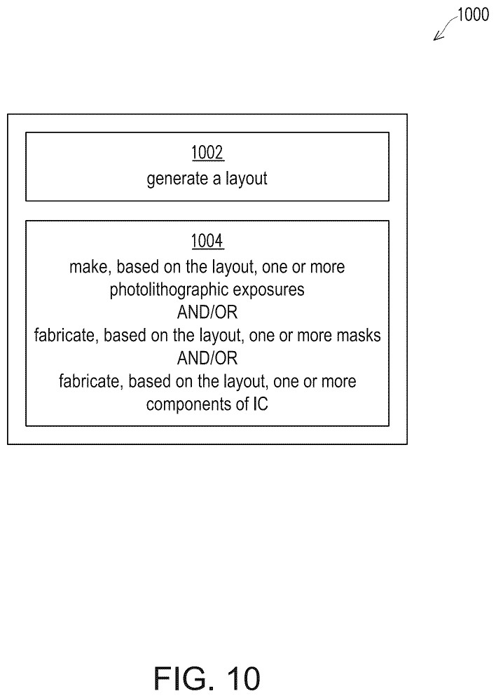

FIG. 10 is a flowchart of a method 1000 of generating a layout and using the layout to manufacture an IC device, in accordance with some embodiments.

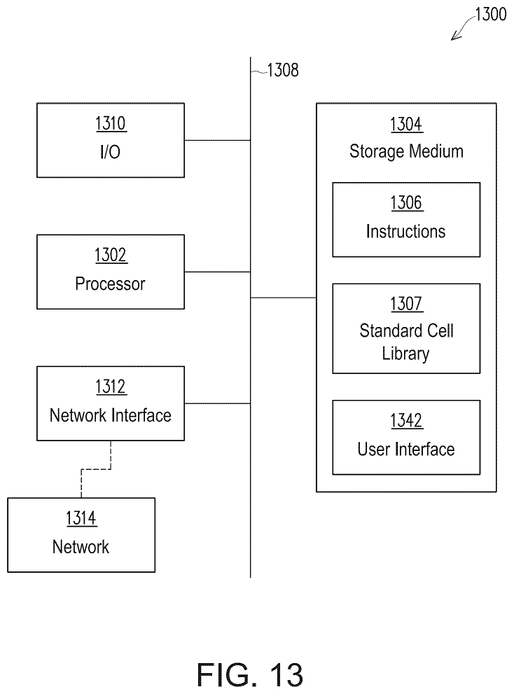

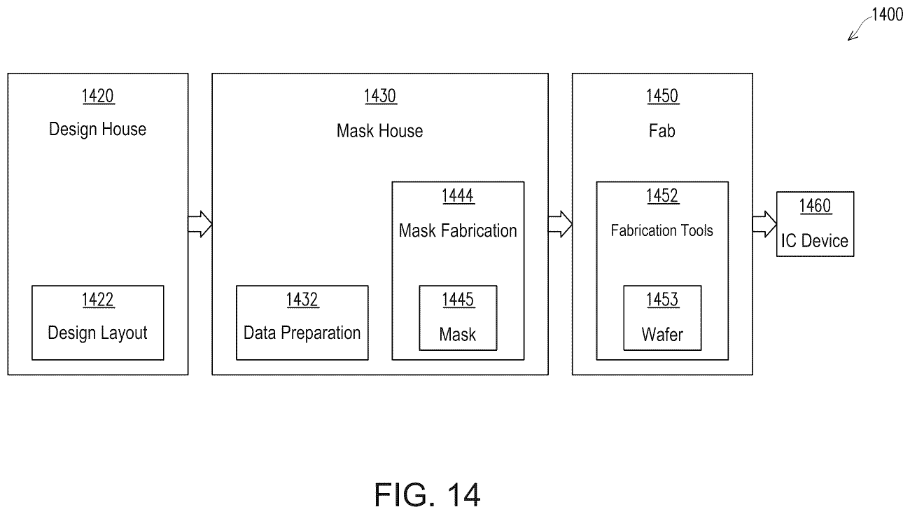

Method 1000 is implementable, for example, using electronic design automation system 1300 (see EDA system 1300 in FIG. 13, discussed below) and an integrated circuit (IC) manufacturing system 1400 (FIG. 14, discussed below), in accordance with some embodiments. Regarding method 1000, examples of the layout include the layouts disclosed herein, or the like. Examples of an IC device to be manufactured according to method 1000 include the IC devices disclosed herein. In FIG. 10, method 1000 includes operations 1002, 1004.

At operation 1002, a layout is generated. In some embodiments, operation 1002 for generating a layout includes selecting a standard cell from among a library of standard cells, the library of standard cells including one or more standard cells representing an FTV. In some embodiments, operation 1002 includes selecting a functional circuit standard cell and standard cell that represents a stand-alone FTV from the library, and placing the functional circuit standard cell and the stand-alone FTV cell in the layout. In some embodiments, the stand-alone FTV cell is a separate cell in the library. In some embodiments, the stand-alone FTV cell does not include an active device such as a transistor or the like. In some embodiments, the stand-alone FTV cell does not include a functional circuit element such as a buffer, inverter, or the like. In some embodiments, the stand-alone FTV cell does not include logic. From operation 1002, flow proceeds to operation 1004.

At operation 1004, based on the layout, at least one of (A) one or more photolithographic exposures are made or (B) one or more semiconductor masks are fabricated or (C) one or more components in a layer of an IC device are fabricated.

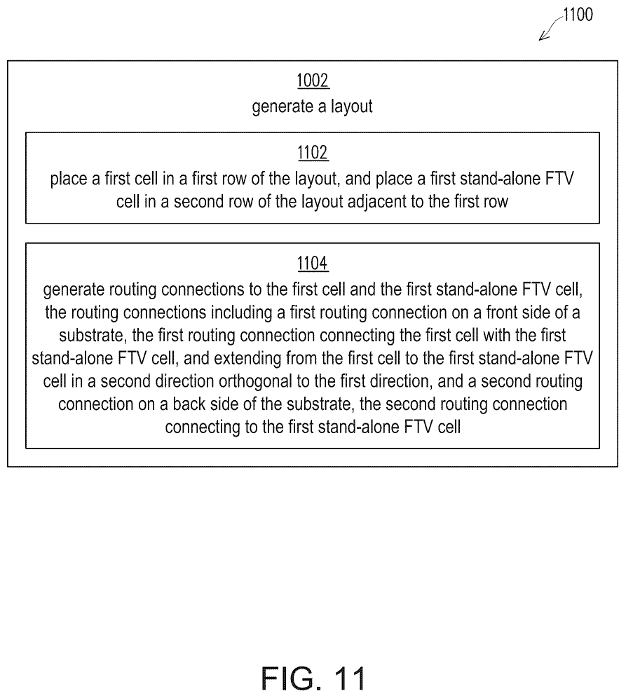

FIG. 11 is a flowchart of a method 1100 of generating a layout, in accordance with some embodiments. More particularly, the flowchart of FIG. 11 shows additional operations that demonstrate one example of procedures implementable in operation 1002 of FIG. 10, in accordance with one or more embodiments. In FIG. 11, operation 1002 includes operations 1102~1104.

At operation 1102, the method includes placing a first cell in a first row of the layout, and placing a first stand-alone FTV cell in a second row of the layout adjacent to the first row.

At operation 1104, the method includes generating routing connections to the first cell and the first stand-alone FTV cell, the routing connections including a first routing connection on a front side of a substrate, the first routing connection connecting the first cell with the first stand-alone FTV cell, and extending from the first cell to the first stand-alone FTV cell in a second direction orthogonal to the first direction, and a second routing connection on a back side of the substrate, the second routing connection connecting to the first stand-alone FTV cell.

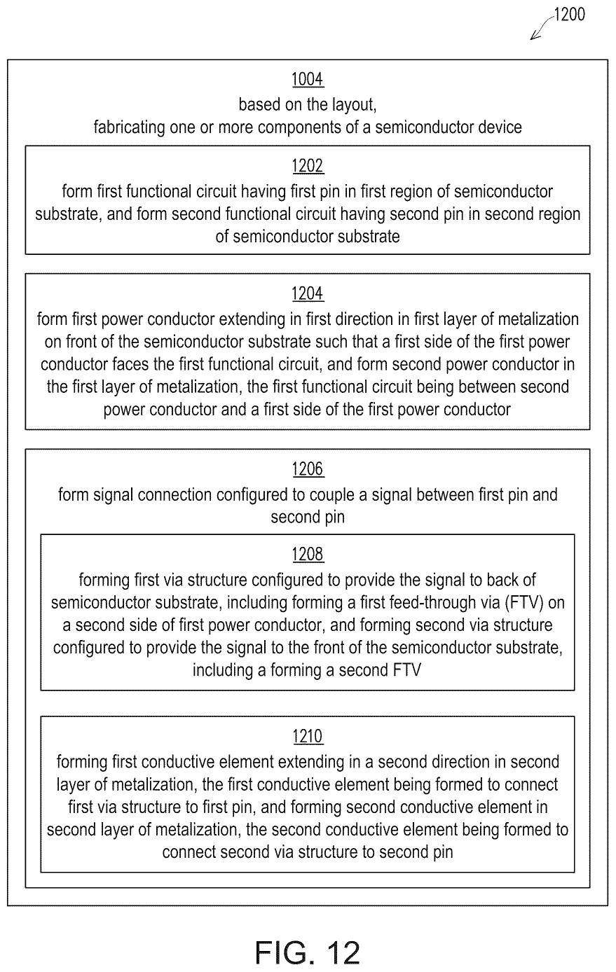

FIG. 12 is a flowchart of a method 1200 of fabricating one or more components of an IC device, in accordance with some embodiments. More particularly, the flowchart of FIG. 12 shows additional operations that demonstrate one example of procedures implementable in operation 1004 of FIG. 10, in accordance with one or more embodiments. In FIG. 12, operation 1004 includes operations 1202~1210.

At operation 1202, a first functional circuit is formed to have a first pin in first region of a semiconductor substrate, and a second functional circuit is formed to have a second pin in a second region of the semiconductor substrate.

At operation 1204, a first power conductor is formed to extend in a first direction in a first layer of metalization, e.g., an M0 layer of metalization, on a front of the semiconductor substrate such that a first side of the first power conductor faces the first functional circuit, and a second power conductor is formed to extend in the first direction in the first layer of metalization, the first functional circuit being arranged between a second power conductor and a first side of the first power conductor.

At operation 1206, a signal connection is formed to couple a signal between the first pin and the second pin. Operation 1206 includes operations 1208-1210.

At operation 1208, a first via structure is formed to provide the signal to a back of semiconductor substrate. Forming the first via structure includes forming a first feed-through via (FTV) on a second side of first power conductor. Operation 1208 also includes forming a second via structure configured to provide the signal to the front of the semiconductor substrate. Forming the second via structure includes a forming a second FTV.

At operation 1210, a first conductive element is formed to extend in a second direction, which in some embodiments is perpendicular to the first direction, in a second layer of metalization, e.g., an M1 layer of metalization which is a first layer of metalization over the M0 layer of metalization. The first conductive element is formed to connect first via structure to the first pin. Operation 1210 also includes forming a second conductive element extending in the second direction in the second layer of metalization. The second conductive element is formed to connect the second via structure to the second pin.

The described methods include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

In some embodiments, at least one method(s) discussed above is performed in whole or in part by at least one EDA system. In some embodiments, an EDA system is usable as part of a design house of an IC manufacturing system discussed below.

FIG. 13 is a block diagram of an electronic design automation (EDA) system 1300 in accordance with some embodiments.

In some embodiments, EDA system 1300 includes an APR system. Methods described herein of designing layouts represent wire routing arrangements, in accordance with one or more embodiments, are implementable, for example, using EDA system 1300, in accordance with some embodiments.

In some embodiments, EDA system 1300 is a general purpose computing device including a hardware processor 1302 and a non-transitory, computer-readable storage medium 1304. The computer-readable storage medium 1304, amongst other things, is encoded with, i.e., stores, computer program code 1306, i.e., a set of executable instructions. Execution of instructions 1306 by the processor 1302 represents (at least in part) an EDA tool which implements a portion or all of the methods described herein in accordance with one or more embodiments (hereinafter, the noted processes and/or methods).

The processor 1302 is electrically coupled to the computer-readable storage medium 1304 via a bus 1308. The processor 1302 is also electrically coupled to an I/O interface 1310 by the bus 1308. A network interface 1312 is also electrically connected to processor 1302 via the bus 1308. Network interface 1312 is connected to a network 1314, so that the processor 1302 and the computer-readable storage medium 1304 are capable of connecting to external elements via network 1314. Processor 1302 is configured to execute computer program code 1306 encoded in the computer-readable storage medium 1304 in order to cause EDA system 1300 to be usable for performing a portion or all of the noted processes and/or methods. In one or more embodiments, processor 1302 is a central processing unit (CPU), a multi-processor, a distributed processing system, an application specific integrated circuit (ASIC), and/or a suitable processing unit.

In one or more embodiments, the computer-readable storage medium 1304 is an electronic, magnetic, optical, electromagnetic, infrared, and/or a semiconductor system (or apparatus or device). Examples of the computer-readable storage medium 1304 include a semiconductor or solid-state memory, a magnetic tape, a removable computer diskette, a random access memory (RAM), a read-only memory (ROM), a rigid magnetic disk, and/or an optical disk. In one or more embodiments using optical disks, the computer-readable storage medium 1304 includes a compact disk-read only memory (CD-ROM), a compact disk-read/write (CD-R/W), and/or a digital video disc (DVD).

In one or more embodiments, the computer-readable storage medium 1304 stores computer program code 1306 configured to cause EDA system 1300 (where such execution represents (at least in part) the EDA tool) to be usable for performing a portion or all of the noted processes and/or methods. In one or more embodiments, the computer-readable storage medium 1304 also stores information which facilitates performing a portion or all of the noted processes and/or methods. In one or more embodiments, the computer-readable storage medium 1304 stores library 1307 of standard cells including such standard cells as disclosed herein.

The EDA system 1300 includes I/O interface 1310. I/O interface 1310 is coupled to external circuitry. In one or more embodiments, I/O interface 1310 includes a keyboard, keypad, mouse, trackball, trackpad, touchscreen, and/or cursor direction keys for communicating information and commands to processor 1302.

The EDA system 1300 also includes network interface 1312 coupled to processor 1302. Network interface 1312 allows EDA system 1300 to communicate with network 1314, to which one or more other computer systems are connected. Network interface 1312 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 1300.

The EDA system 1300 is configured to receive information through I/O interface 1310. The information received through I/O interface 1310 includes one or more of instructions, data, design rules, libraries of standard cells, and/or other parameters for processing by processor 1302. The information is transferred to processor 1302 via the bus 1308. EDA system 1300 is configured to receive information related to a user interface (UI) through I/O interface 1310. The information is stored in the computer-readable storage medium 1304 as user interface (UI) 1342.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1300. In some embodiments, a layout that includes standard cells is generated using a tool such as VIRTUOSO® available from Cadence Design Systems, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 14 is a block diagram of an integrated circuit (IC) manufacturing system 1400, and an IC manufacturing flow associated therewith, in accordance with some embodiments. In some embodiments, based on a layout, at least one of (A) one or more semiconductor masks or (B) at least one component in a layer of a semiconductor integrated circuit is fabricated using the IC manufacturing system 1400.

In FIG. 14, the IC manufacturing system 1400 includes entities, such as a design house 1420, a mask house 1430, and an IC manufacturer/fabricator (“fab”) 1450, that interact with one another in the design, development, and manufacturing cycles and/or services related to manufacturing an IC device 1460. The entities in the IC manufacturing system 1400 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of the design house 1420, the mask house 1430, and the IC fab 1450 are owned by a single larger company. In some embodiments, two or more of the design house 1420, the mask house 1430, and the IC fab 1450 coexist in a common facility and use common resources.

The design house (or design team) 1420 generates an IC design layout 1422. The IC design layout 1422 includes various geometrical patterns designed for an IC device 1460. The geometrical patterns correspond to patterns of metal, oxide, or semiconductor layers that make up the various components of the IC device 1460 to be fabricated. The various layers combine to form various IC features. For example, a portion of the IC design layout 1422 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. The design house 1420 implements a formal design procedure to form the IC design layout 1422. The design procedure includes one or more of logic design, physical design, or place-and-route operation. The IC design layout 1422 is presented in one or more data files having information of the geometrical patterns. For example, the IC design layout 1422 can be expressed in a GDSII file format or DFII file format.

The mask house 1430 includes mask data preparation 1432 and mask fabrication 1444. The mask house 1430 uses the IC design layout 1422 to manufacture one or more masks 1445 to be used for fabricating the various layers of the IC device 1460 according to the IC design layout 1422. The mask house 1430 performs the mask data preparation 1432, where the IC design layout 1422 is translated into a representative data file (“RDF”). The mask data preparation 1432 provides the RDF to the mask fabrication 1444. The mask fabrication 1444 includes a mask writer. The mask writer converts the RDF to an image on a substrate, such as a mask (reticle) 1445 or a semiconductor wafer 1453. The IC design layout 1422 is manipulated by the mask data preparation 1432 to comply with particular characteristics of the mask writer and/or requirements of the IC fab 1450. In FIG. 14, the mask data preparation 1432 and the mask fabrication 1444 are illustrated as separate elements. In some embodiments, the mask data preparation 1432 and the mask fabrication 1444 can be collectively referred to as mask data preparation.

In some embodiments, the mask data preparation 1432 includes optical proximity correction (OPC) that uses lithography enhancement techniques to compensate for image errors, such as those that can arise from diffraction, interference, other process effects, and the like. The OPC adjusts the IC design layout 1422. In some embodiments, the mask data preparation 1432 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 1432 includes a mask rule checker (MRC) that checks the IC design layout 1422 that has undergone processes in the OPC with a set of mask creation rules containing geometric and/or connectivity restrictions to ensure sufficient margins, to account for variability in semiconductor manufacturing processes, and the like. In some embodiments, the MRC modifies the IC design layout 1422 to compensate for limitations during the mask fabrication 1444, which may undo part of the modifications performed by OPC in order to meet mask creation rules.

In some embodiments, the mask data preparation 1432 includes lithography process checking (LPC) that simulates processing that will be implemented by the IC fab 1450 to fabricate the IC device 1460. The LPC simulates this processing based on the IC design layout 1422 to create a simulated manufactured device, such as the IC device 1460. The processing parameters in LPC simulation can include parameters associated with various processes of the IC manufacturing cycle, parameters associated with tools used for manufacturing the IC, and/or other aspects of the manufacturing process. The LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are repeated to further refine the IC design layout 1422.

It should be understood that the above description of the mask data preparation 1432 has been simplified for the purposes of clarity. In some embodiments, the mask data preparation 1432 includes additional features such as a logic operation (LOP) to modify the IC design layout 1422 according to manufacturing rules. Additionally, the processes applied to the IC design layout 1422 during the mask data preparation 1432 may be executed in a variety of different orders.

After the mask data preparation 1432 and during the mask fabrication 1444, a mask 1445 or a group of masks 1445 are fabricated based on the modified IC design layout 1422. In some embodiments, the mask fabrication 1444 includes performing one or more lithographic exposures based on the IC design layout 1422. In some embodiments, an electron-beam (e-beam) or a mechanism of multiple e-beams is used to form a pattern on a mask (photomask or reticle) 1445 based on the modified IC design layout 1422. The mask 1445 can be formed in various technologies. In some embodiments, the mask 1445 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of the mask 1445 includes a transparent substrate (e.g., fused quartz) and an opaque material (e.g., chromium) coated in the opaque regions of the binary mask. In another example, the mask 1445 is formed using a phase shift technology. In a phase shift mask (PSM) version of the mask 1445, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 1444 is used in a variety of processes. For example, such a mask(s) is used in an ion implantation process to form various doped regions in a semiconductor wafer 1453, in an etching process to form various etching regions in the semiconductor wafer 1453, and/or in other suitable processes.

The IC fab 1450 is an IC fabrication business that includes one or more manufacturing facilities for the fabrication of a variety of different IC products. In some embodiments, the IC fab 1450 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

The IC fab 1450 includes fabrication tools 1452 configured to execute various manufacturing operations on semiconductor wafer 1453 such that the IC device 1460 is fabricated in accordance with the mask(s), e.g., the mask 1445. In various embodiments, the fabrication tools 1452 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

The IC fab 1450 uses the mask(s) 1445 fabricated by the mask house 1430 to fabricate the IC device 1460. Thus, the IC fab 1450 at least indirectly uses the IC design layout 1422 to fabricate the IC device 1460. In some embodiments, the semiconductor wafer 1453 is fabricated by the IC fab 1450 using the mask(s) 1445 to form the IC device 1460. In some embodiments, the IC fabrication includes performing one or more lithographic exposures based at least indirectly on the IC design layout 1422. The semiconductor wafer 1453 includes a silicon substrate or other proper substrate having material layers formed thereon. The semiconductor wafer 1453 further includes one or more of various doped regions, dielectric features, multilevel interconnects, and the like (formed at subsequent manufacturing steps).

Details regarding an integrated circuit (IC) manufacturing system (e.g., the IC manufacturing system 1400 of FIG. 14), and an IC manufacturing flow associated therewith are found, e.g., in U.S. Pat. No. 9,256,709, granted Feb. 9, 2016, U.S. Pre-Grant Publication No. 2015/0278429, published Oct. 1, 2015, U.S. Pre-Grant Publication No. 2014/0040838, published Feb. 6, 2014, and U.S. Pat. No. 7,260,442, granted Aug. 21, 2007, the entireties of each of which are hereby incorporated by reference.

In some embodiments, a layout is generated using standard cells from a cell library. The standard cells include at least a first cell and a first stand-alone feed-through via (FTV) cell, the first cell including a transistor, and the first stand-alone FTV cell including a first FTV and being free of a transistor; placing the first cell in a first row of the layout, the first row extending in a first direction; placing the first stand-alone FTV cell in a second row of the layout, the second row extending in the first direction and being adjacent to the first row; generating routing connections to the first cell and the first stand-alone FTV cell, the routing connections including: a first routing connection on a first side of a substrate, the first routing connection connecting the first cell with the first stand-alone FTV cell, and extending from the first cell to the first stand-alone FTV cell in a second direction orthogonal to the first direction, and a second routing connection on a second side of the substrate, the second side being opposite the first side, the second routing connection connecting to the first stand-alone FTV cell; and generating an IC design based on the layout.

In some embodiments, a method of manufacturing an integrated circuit (IC) device includes: generating a layout using standard cells from a cell library, the standard cells including at least a first cell, a second cell, and stand-alone feed-through via (FTV) cell, the first cell including a transistor, the second cell including a transistor, and being the same as or different from the first cell, and the stand-alone FTV cell including an FTV and being free of a transistor; placing the first cell in a first row of the layout; placing a first instance of the stand-alone FTV cell in a second row of the layout, the second row being adjacent to the first row; placing the second cell in a row of the layout that is the same as or different from the first and second rows; placing a second instance of the stand-alone FTV cell in a row of the layout that is the same as or different from the first and second rows; generating routing connections to the first cell, the second cell, and the first and second instances of the stand-alone FTV cell, the routing connections including: a first routing connection on a first side of a substrate, the first routing connection connecting the first cell with the first instance of the stand-alone FTV cell, a second routing connection on a second side of the substrate, the second side being opposite the first side, the second routing connection connecting the first instance of the stand-alone FTV cell with the second instance of the stand-alone FTV cell, and a third routing connection on the first side of the substrate, the third routing connection connecting the second instance of the stand-alone FTV cell with the second cell; evaluating a timing characteristic of a first circuit section of the layout by treating the first circuit section as a single net, the first circuit section including: the first routing connection, a first FTV in the first instance of the stand-alone FTV cell, the second routing connection, a second FTV in the second instance of the stand-alone FTV cell, and the third routing connection; and generating an IC design based on the layout.

In some embodiments, a system for manufacturing an integrated circuit (IC) device includes: at least one memory configured to store device layout data, the memory including a non-transitory computer-readable medium; and at least one processor configured to: access the at least one memory and retrieve the device layout data; generate a device layout from the device layout data; and generate an IC design based on the layout, the generating the device layout including: selecting standard cells from a cell library, the standard cells including at least a first cell and a first stand-alone feed-through via (FTV) cell, the first cell including a transistor, and the first stand-alone FTV cell including an FTV and being free of a transistor; placing the first cell in a first row of the layout, the first row extending in a first direction; placing the first stand-alone FTV cell in a second row of the layout, the second row extending in the first direction and being adjacent to the first row; and generating routing connections to the first cell and the first stand-alone FTV cell, the routing connections including: a first routing connection on a first side of a substrate, the first routing connection connecting the first cell with the first stand-alone FTV cell, and extending from the first cell to the first stand-alone FTV cell in a second direction orthogonal to the first direction, and a second routing connection on a second side of the substrate, the second side being opposite the first side, the second routing connection connecting to the first stand-alone FTV cell.

In some embodiments, a semiconductor device includes: a first functional circuit having a first pin in a first region of a substrate; a first power conductor extending in a first direction in a first layer of metalization on a front of the substrate; a second power conductor in the first layer of metalization, the first functional circuit being between the second power conductor and a first side of the first power conductor; a second functional circuit having a second pin in a second region of the substrate; and a signal connection configured to couple a signal between the first pin and the second pin. The signal connection includes: a first conductive element extending in a second direction in a second layer of metalization, the first conductive element being connected to the first pin on the first side of the first power conductor; a first via structure connecting the first conductive element to a back of the substrate, the first via structure including a first feed-through via (FTV) on a second side of the first power conductor; a second via structure configured to provide the signal to the front of the substrate, the second via structure including a second FTV; and a second conductive element in the second layer of metalization, the second conductive element being connected to the second via structure and the second pin.

In some embodiments, a method of fabricating a semiconductor device includes: forming a first functional circuit having a first pin in a first region of a substrate; forming a second functional circuit having a second pin in a second region of the substrate; forming a first power conductor extending in a first direction in a first layer of metalization on a front of the substrate such that a first side of the first power conductor faces the first functional circuit; forming a second power conductor in the first layer of metalization, the first functional circuit being between the second power conductor and a first side of the first power conductor; forming a signal connection configured to couple a signal between the first pin and the second pin, the forming the signal connection including: forming a first via structure configured to provide the signal to a back of the substrate, the forming the first via structure including forming a first feed-through via (FTV) on a second side of the first power conductor; forming a second via structure configured to provide the signal to the front of the substrate, the forming the second via structure including a forming a second FTV; forming a first conductive element extending in a second direction in a second layer of metalization, the first conductive element being formed to connect the first via structure to the first pin; and forming a second conductive element in the second layer of metalization, the second conductive element being formed to connect the second via structure to the second pin.

In some embodiments, an integrated circuit includes: first and second circuits on a first face of a substrate, the first and second circuits being connected together by a conductive path that includes conductors on a second face of the substrate, opposite the first face, the conductive path including: a first conductive element coupling an input or output of the first circuit to a first via structure, the input or output of the first circuit being on an opposite side of a first power conductor from the first via structure, the first power conductor extending in a first direction in a first layer of metalization on the first face of the substrate, and the first conductive element extending in a second direction in a second layer of metalization over the first layer of metalization; and a second conductive element in the second layer of metalization, the second conductive element being connected to a second via structure and an input or output of the second circuit. The first via structure connects the first conductive element to the conductors on the second face of the substrate, the first via structure including a first feed-through via (FTV) on one side of the first power conductor. The second via structure connects the conductors on the second face of the substrate to the second conductive element, the second via structure including a second FTV.

In some embodiments, a method of fabricating a semiconductor device includes: forming a first functional circuit having a first pin in a first region of a substrate; forming a second functional circuit having a second pin in a second region of the substrate; forming a first power conductor extending in a first direction in a first layer of metalization on a front of the substrate such that a first side of the first power conductor faces the first functional circuit; forming a second power conductor in the first layer of metalization, the first functional circuit being between the second power conductor and the first side of the first power conductor; forming a signal connection configured to couple a signal between the first pin and the second pin, the forming the signal connection including: forming a first via structure configured to provide the signal to a back of the substrate, the forming the first via structure including forming a first feed-through via (FTV) on a second side of the first power conductor; forming a second via structure configured to provide the signal to the front of the substrate, the forming the second via structure including forming a second FTV; forming a first conductive element extending in a second direction in a second layer of metalization, the first conductive element being formed to connect the first via structure to the first pin; and forming a second conductive element in the second layer of metalization, the second conductive element being formed to connect the second via structure to the second pin.

In some embodiments, a method of fabricating a semiconductor device includes: forming first and second functional circuits on a first face of a substrate, wherein: the first functional circuit includes a first pin, and the second functional circuit includes a second pin; forming a first power conductor extending in a first direction in a first layer of metalization on the first face of the substrate; forming a first conductive element extending in a second direction in a second layer of metalization over the first layer of metalization; forming a second conductive element in the second layer of metalization; forming a first feed-through via (FTV), wherein: the first FTV is formed on an opposite side of the first power conductor from the first pin, and forming the first conductive element includes coupling the first FTV to the first pin; forming a second FTV, wherein: forming the second conductive element includes coupling the second FTV to the second pin; and forming one or more back-side conductors on a second face of the substrate, opposite the first face, wherein: the one or more back-side conductors couple the first FTV to the second FTV.

In some embodiments, a method of fabricating a semiconductor device includes: forming first and second functional circuits on a first face of a substrate in respective first and second circuit cells, wherein: the first functional circuit includes a first pin in the first circuit cell, and the second functional circuit includes a second pin in the second circuit cell; forming a first power conductor extending in a first direction in a first layer of metalization on the first face of the substrate; forming a first conductive element extending in a second direction in a second layer of metalization over the first layer of metalization; forming a second conductive element in the second layer of metalization; forming first and second feed-through vias (FTVs) extending through the substrate in respective first and second FTV cells, wherein: the first and second FTV cells are each formed to be free of a transistor, the first FTV is formed on an opposite side of the first power conductor from the first pin, forming the first conductive element includes coupling the first FTV to the first pin, and forming the second conductive element includes coupling the second FTV to the second pin; and forming one or more back-side conductors on a second face of the substrate, opposite the first face, wherein: the one or more back-side conductors couple the first FTV to the second FTV.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, the method comprising:
forming a first functional circuit having a first pin in a first region of a substrate;
forming a second functional circuit having a second pin in a second region of the substrate;
forming a first power conductor extending in a first direction in a first layer of metalization on a front of the substrate such that a first side of the first power conductor faces the first functional circuit;
forming a second power conductor in the first layer of metalization, the first functional circuit being between the second power conductor and the first side of the first power conductor;
forming a signal connection configured to couple a signal between the first pin and the second pin, the forming the signal connection including:
forming a first via structure configured to provide the signal to a back of the substrate, the forming the first via structure including forming a first feed-through via (FTV) on a second side of the first power conductor;
forming a second via structure configured to provide the signal to the front of the substrate, the forming the second via structure including forming a second FTV;
forming a first conductive element extending in a second direction in a second layer of metalization, the first conductive element being formed to connect the first via structure to the first pin; and
forming a second conductive element in the second layer of metalization, the second conductive element being formed to connect the second via structure to the second pin.

2. The method of claim 1, wherein the forming a first conductive element includes:
forming the first conductive element to vertically overlap the first FTV.

3. The method of claim 1, wherein the forming a first conductive element includes:
forming the first conductive element such that the first conductive element vertically overlaps the first pin.

4. The method of claim 1, wherein the forming the second conductive element includes:
forming the second conductive element to extend in the second direction and vertically overlap the second FTV.

5. The method of claim 1, wherein forming the first and second functional circuits includes:
forming the first and second functional circuits to be multi-pin circuits having all pins on the front of the substrate.

6. The method of claim 1, wherein:
the first functional circuit is formed in a first circuit cell,
the second functional circuit is formed in a second circuit cell,
the first FTV is formed in a first FTV cell, and
the second FTV is formed in a second FTV cell.

7. The method of claim 6, wherein:
the first circuit cell is in a first row, the first FTV cell is in a second row, and the first and second rows are adjacent rows, and
the second circuit cell is in a third row, the second FTV cell is in a fourth row, and the third and fourth rows are adjacent rows.

8. The method of claim 7, wherein:
the first conductive element is formed to extend across a common horizontal boundary of the first circuit cell and the first FTV cell, and
the second conductive element is formed to extend across a common horizontal boundary of the second circuit cell and the second FTV cell.

9. The method of claim 6, wherein:
the first and second FTV cells are each formed to be free of a transistor.

10. The method of claim 1, further comprising:
forming one or more back-side conductors on the back of the substrate, the one or more back-side conductors coupling the first FTV to the second FTV.

11. The method of claim 10, further comprising:
forming a first back-side metalization layer, a second back-side metalization layer, and a third back-side metalization layer, wherein:
the first back-side metalization layer is between the substrate and the second back-side metalization layer, and the second back-side metalization layer is between the first back-side metalization layer and the third back-side metalization layer, and
at least one of the one or more back-side conductors coupling the first FTV to the second FTV is formed in the third back-side metalization layer.

12. The method of claim 1, further comprising:
forming a first metal-to-oxide diffusion (MD) contact; and
forming a second MD contact,
wherein the first and second pins respectively correspond to the first and second MD contacts.

13. The method of claim 1, wherein:
the first functional circuit is formed in a first circuit cell,
the second functional circuit is formed in a second circuit cell,
the first and second circuit cells are each formed to be free of an FTV.

14. The method of claim 1, wherein:
the first conductive element is formed such that a centerline of the first conductive element, which extends along the second direction, is about 1 contact poly pitch (CPP) or less from a centerline of the first FTV, relative to the first direction.

15. A method of fabricating a semiconductor device, the method comprising:
forming first and second functional circuits on a first face of a substrate, wherein:
the first functional circuit includes a first pin, and
the second functional circuit includes a second pin;
forming a first power conductor extending in a first direction in a first layer of metalization on the first face of the substrate;
forming a first conductive element extending in a second direction in a second layer of metalization over the first layer of metalization;
forming a second conductive element in the second layer of metalization;
forming a first feed-through via (FTV), wherein:
the first FTV is formed on an opposite side of the first power conductor from the first pin, and
forming the first conductive element includes coupling the first FTV to the first pin;
forming a second FTV, wherein:
forming the second conductive element includes coupling the second FTV to the second pin; and
forming one or more back-side conductors on a second face of the substrate, opposite the first face, wherein:
the one or more back-side conductors couple the first FTV to the second FTV.

16. The method of claim 15, further comprising:
forming a second power conductor extending in the first direction in the first layer of metalization on the first face of the substrate, wherein:
the second FTV is formed on an opposite side of the second power conductor from the second pin.

17. The method of claim 16, wherein:
the first functional circuit is formed in a first circuit cell,
the second functional circuit is formed in a second circuit cell,
the first FTV is formed in a first FTV cell,
the second FTV is formed in a second FTV cell,
the first circuit cell is in a first row, the first FTV cell is in a second row, and the first and second rows are adjacent rows, and
the second circuit cell is in a third row, the second FTV cell is in a fourth row, and the third and fourth rows are adjacent rows.

18. The method of claim 17, wherein:
the first conductive element is formed to extend across a common horizontal boundary of the first circuit cell and the first FTV cell, and
the second conductive element is formed to extend across a common horizontal boundary of the second circuit cell and the second FTV cell.

19. The method of claim 18, wherein:
the first and second FTV cells are each formed to be free of a transistor.

20. A method of fabricating an integrated circuit, the method comprising:
forming first and second functional circuits on a first face of a substrate in respective first and second circuit cells, wherein:
the first functional circuit includes a first pin in the first circuit cell, and the second functional circuit includes a second pin in the second circuit cell;
forming a first power conductor extending in a first direction in a first layer of metalization on the first face of the substrate;
forming a first conductive element extending in a second direction in a second layer of metalization over the first layer of metalization;
forming a second conductive element in the second layer of metalization;
forming first and second feed-through vias (FTVs) extending through the substrate in respective first and second FTV cells, wherein:
the first and second FTV cells are each formed to be free of a transistor,
the first FTV is formed on an opposite side of the first power conductor from the first pin,
forming the first conductive element includes coupling the first FTV to the first pin, and
forming the second conductive element includes coupling the second FTV to the second pin; and
forming one or more back-side conductors on a second face of the substrate, opposite the first face, wherein:
the one or more back-side conductors couple the first FTV to the second FTV.
